(19) United States
(12) Patent Application Publication
(10) Pub. No.: US 2012/0256647 A1
(43) Pub. Date: Oct. 11, 2012

(54) CAPACITANCE SENSOR STRUCTURE

(75) Inventors: Yi-Hsin TAO, Hsinchu City (TW); Chia-Hsing LIN, Hsinchu City (TW); Che-Hao HSU, New Taipei City (TW); Wen-Jun HSU, Hsinchu City (TW)

(73) Assignee: ELAN MICROELECTRONICS CORPORATION, Hsinchu (TW)

(21) Appl. No.: 13/441,483

(22) Filed: Apr. 6, 2012

(30) Foreign Application Priority Data
Apr. 7, 2011 (TW) 100112107

(51) Int. Cl. G01R 27/26

(52) U.S. Cl. 324/686

(57) ABSTRACT

A capacitance sensor structure includes a first sensor in a first direction and a second sensor in a second direction for sensing a variation in the mutual capacitance between the first sensor and the second sensor by applying an excitation signal to the first sensor and detecting a response signal from the second sensor. The sensing area of the second sensor is intentionally reduced to be much smaller than the sensing area of the first sensor for noise performance improvement of the mutual capacitance sensing.

### FIELD OF THE INVENTION

The present invention is related generally to a capacitive touch control device and, more particularly, to a capacitance sensor structure.

### BACKGROUND OF THE INVENTION

The working principle of capacitive touch control technology is based on the capacitance sensors of a capacitive touch control device to sense the capacitance variation caused by a touch of one or more fingers or other conductors. For current capacitive touch control devices, the capacitance to be sensed can be divided into two types: the self capacitance between a sensor and a ground plane, and the mutual capacitance between two sensors. FIG. 1 schematically shows how a finger touch on a capacitive touch control device changes the mutual capacitance thereof, in which lines 10 and 12 represent an X sensor in a first direction and a Y sensor in a second direction respectively, capacitances Cx and Cy represent the self capacitances of the X sensor 10 and the Y sensor 12 respectively, and capacitance Cxy represents the mutual capacitance between the X sensor 10 and the Y sensor 12. In an ordinary capacitive touch control device, the X sensor 10 and the Y sensor 12 have similar shapes and widths. For mutual capacitance sensing, conventionally, a sensing circuit 14 applies an excitation signal Tx to the Y sensor 12 and detects the response signal Rx from the X sensor 10 for sensing the variation of the mutual capacitance between the X sensor 10 and the Y sensor 12. If the intersection 18 of the X sensor 10 and the Y sensor 12 is not touched, it will be the mutual capacitance Cxy sensed by the sensing circuit 14. However, if a finger touches at the intersection 18 of the X sensor 10 and the Y sensor 12, the finger can be regarded as an equivalent circuit 16 having a grounded extremely high capacitance Chm, and capacitances Cfx and Cfy occur between the finger and the X sensor 10 and the Y sensor 12 respectively, so that the mutual capacitance sensed by the sensing circuit 14 is changed from Cxy to a capacitance equivalent to Cfx and Cfy connected in series. Therefore, by sensing the variation in the mutual capacitance, the sensing circuit 14 can identify whether the intersection 18 is touched.

When sensing the mutual capacitance Cxy or the serially connected Cfy and Cfx from the X sensor 10, the mutual capacitance Cxy or the serially connected Cfy and Cfx may be regarded as a filter and thus filter out the noise imparted on the Y sensor 12, and thus the interference caused by such noise to the sensing circuit 14 is minimized. However, the noise imparted on the X sensor 10 will go into the sensing circuit 14 directly, and the larger sensing area the X sensor 10 has, the more significant the interference will be to the sensing of the sensing circuit 14.

### SUMMARY OF THE INVENTION

An objective of the present invention is to provide a capacitance sensor structure.

Another objective of the present invention is to provide a capacitance sensor structure for noise performance improvement of mutual capacitance sensing.

According to the present invention, a capacitance sensor structure includes a first sensor in a first direction and a second sensor in a second direction for sensing a variation in the mutual capacitance between the first sensor and the second sensor by applying an excitation signal to the first sensor and detecting a response signal from the second sensor. The sensing area of the second sensor is intentionally reduced to be much smaller than the sensing area of the first sensor for noise performance improvement of the mutual capacitance sensing.

In an embodiment, each of the first sensor and the second sensor has a strip-like shape, and the second sensor has a much smaller width than the second sensor.

In another embodiment, the second sensor is split into a plurality of parallel traces electrically connected together.

In yet another embodiment, the first sensor and the second sensor are made from a same conductor layer, the second sensor divides the first sensor into a plurality of sections, and the adjacent sections of the first sensor are electrically connected to each other by a bridge line spanning the second sensor.

In still another embodiment, the second sensor has holes to reduce its effective sensing area.

In a further embodiment, the second sensor has a hole and at least a dummy sensing piece in the hole.

In yet a further embodiment, the first sensor and the second sensor have ragged borders therebetween.

### BRIEF DESCRIPTION OF THE DRAWINGS

These and other objectives, features and advantages of the present invention will become apparent to those skilled in the art upon consideration of the following description of the preferred embodiments of the present invention taken in conjunction with the accompanying drawings, in which:

FIG. 1 schematically shows how a finger touch on a capacitive touch control device changes the mutual capacitance thereof;

FIG. 2 is a schematic view of a first embodiment according to the present invention;

FIG. 3 is a schematic view of a second embodiment according to the present invention;

FIG. 4 is a schematic view of a third embodiment according to the present invention;

FIG. 5 is a schematic view of a fourth embodiment according to the present invention;

FIG. 6 is a schematic view of a fifth embodiment according to the present invention;

FIG. 7 is a schematic view of a sixth embodiment according to the present invention;

FIG. 8 is a schematic view of a seventh embodiment according to the present invention;

FIG. 9A is a schematic view of an eighth embodiment according to the present invention; and

FIG. 9B is an enlarged view of the sensing units of an X sensor in the embodiment of FIG. 9A.

### DETAILED DESCRIPTION OF THE INVENTION

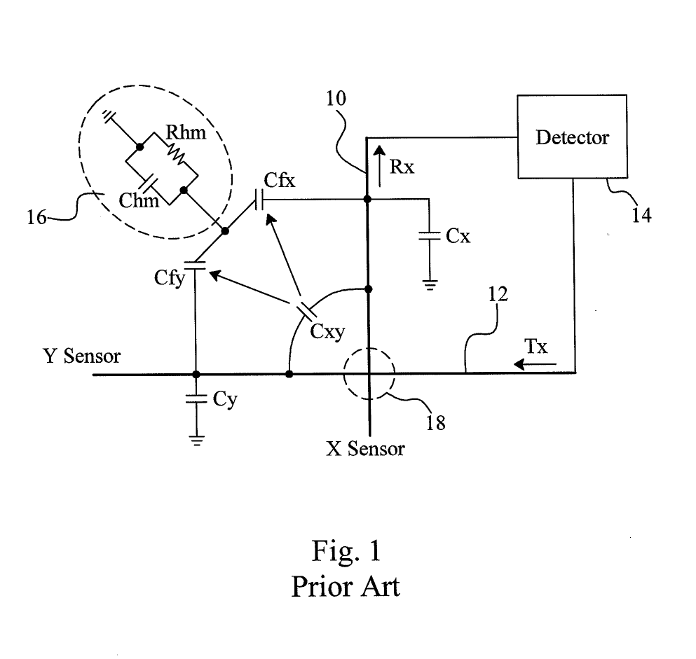

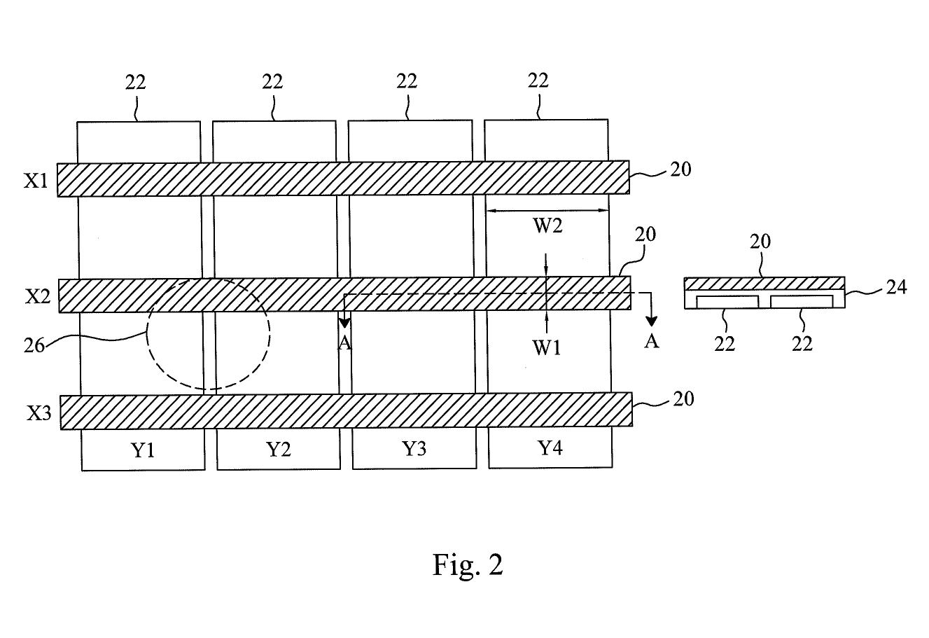

FIG. 2 is a schematic view of a first embodiment according to the present invention, in which the left part shows the layout of the capacitance sensors, and the right part shows a sectional view taken along the line A-A in the left layout. This embodiment demonstrates a structure of capacitance sensors constructed by two conductor layers, which includes strip-like capacitance sensors 20 made from a first conductor layer and arranged in a first direction with Nos. X1, X2 and X3, and strip-like capacitance sensors 22 made from a second conductor layer and arranged in a second direction perpendicular to the first direction with Nos. Y1, Y2, Y3 and Y4, and an insulator layer 24 between the two conductor layers to electrically isolate the X sensors 20 and the Y sensors 22. In particularly, the X sensor 20 has a different sensing area from the Y sensor 22. In this embodiment, the X sensor 20 is much shallower than the Y sensor 22, so that the sensing area of the X sensor 20 is much smaller than that of the Y sensor 22. For instance, in contrast to the conventional capacitance sensors, the width W1 of each X sensor 20 is reduced to ¼ or less of the width W2 of each Y sensor 22. For touch position detection, the X sensors 20 and the Y sensors 22 are connected to a sensing circuit (not shown in FIG. 2) as that shown in FIG. 1 to sense the variation in the mutual capacitance between the sensors 20 and the Y sensors 22. For example, the sensing circuit can detect a touch position by applying an excitation signal to the Y sensors 22 and detecting the response signal from the X sensors 20 to sense the mutual capacitance between the X sensors 20 and the Y sensors 22. Since each X sensor 20 has a much reduced sensing area, the noise that may directly go into the sensing circuit is significantly reduced and consequently, the interference caused by such noise on capacitance sensing is reduced. In addition, if the width W2 of each Y sensor 22 is increased to be larger than the conventional Y sensors, the Y sensors 22 may further has an effect of shielding the interference caused by the underlying circuit in operation to the X sensors 20.

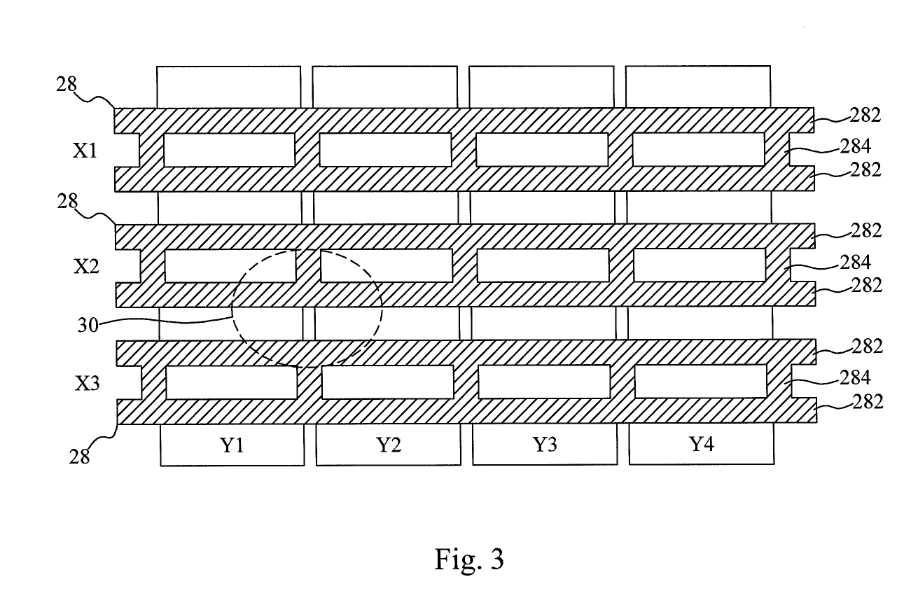

FIG. 3 is a schematic view of an embodiment with a split structure of capacitance sensors, in which each X sensor 28 includes at least two relatively narrow parallel traces 282. More particularly, the spacing between each two adjacent parallel traces 282 is smaller than the size of a finger or conductor to be sensed. The parallel traces 282 in each X sensor 28 are electrically connected to each other by conductive wires 284 provided in the gap between the parallel traces 282 as shown in FIG. 3, or by conductive wires provided elsewhere, e.g., the interconnections or peripheral traces of a printed circuit board. When a finger is placed at the position 30, the finger covers the X sensors X2 and X3 simultaneously, and thus the sensing circuit may sense the mutual capacitance variation from both the X sensors X2 and X3. This improves the spatial linearity because of the smoothed capacitance sensing response and increases the accuracy of identified position.

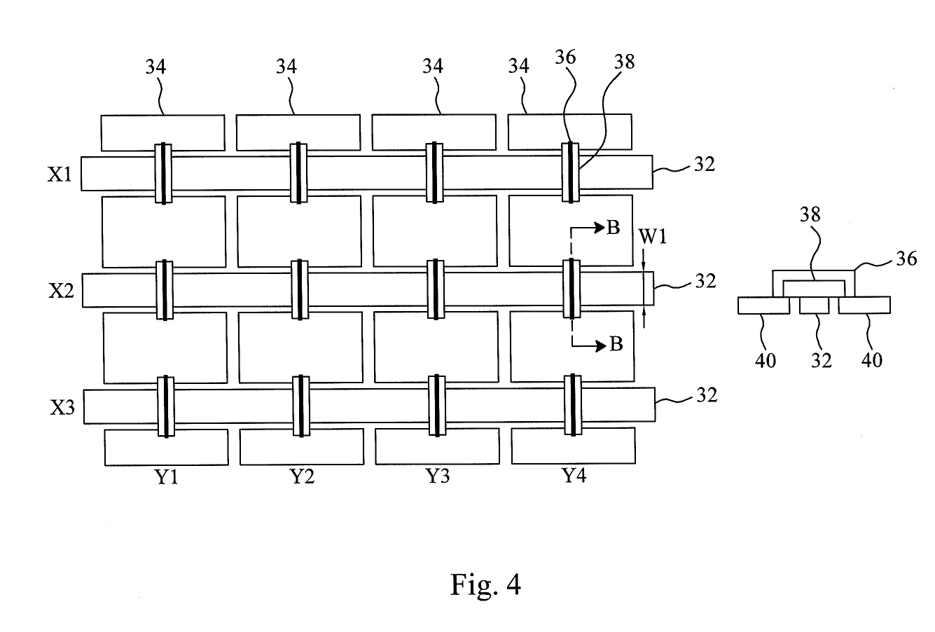

FIG. 4 is a schematic view of a third embodiment according to the present invention, in which the left part shows the layout of the capacitance sensors, and the right part shows a sectional view taken along the line B-B in the left layout. This embodiment demonstrates a structure of capacitance sensors constructed by merely one conductor layer, i.e., all the X sensors 32 and the Y sensors 34 are made from a same conductor layer, with each Y sensor 34 divided by the X sensors 32 into a plurality of sections 40. The separate sections 40 of each Y sensor 34 are electrically connected by bridge lines 36, each bridge line 36 spans one corresponding X sensor 32 and is electrically isolated from the corresponding X sensor 32 by an insulator layer 38. The same as that of FIG. 2, the width W1 of each X sensor 32 is much reduced so that the sensing area of the X sensor 32 is much smaller than that of the Y sensor 34. For example, the width W1 of each X sensor 32 is reduced to ¼ or less of the width W2 of each Y sensor 34. For touch position detection, the X sensors 32 and the Y sensors 34 are connected to a sensing circuit (not shown in FIG. 4) as that shown in FIG. 1 to sense the variation in the mutual capacitance between the X sensors 32 and the Y sensors 34. For example, the sensing circuit can detect a touch position by applying an excitation signal to the Y sensors 34 and detecting the response signal from the X sensors 32 to sense the mutual capacitance between the X sensors 32 and the Y sensors 34.

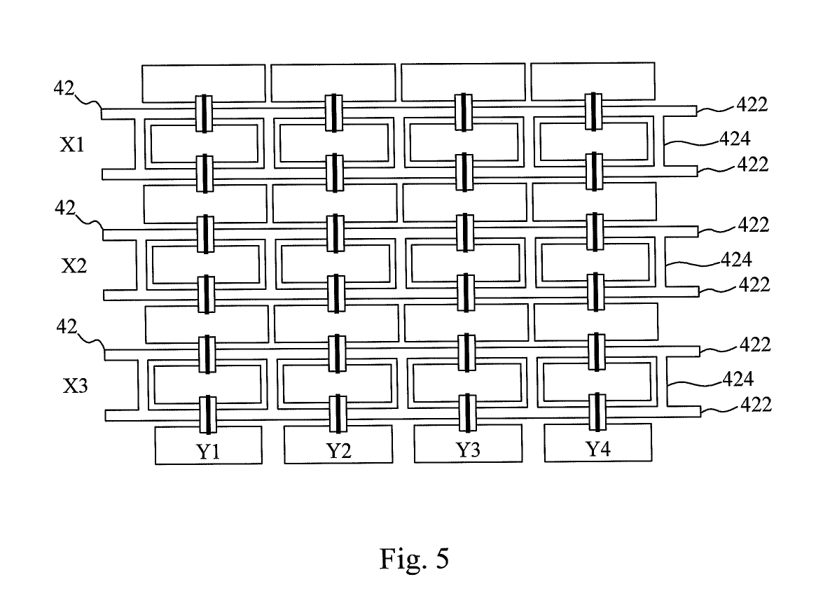

FIG. 5 is a schematic view of an embodiment modified from the embodiment shown in FIG. 4 by splitting each X sensor 42 into relatively narrow parallel traces 422. Similar to the embodiment shown in FIG. 3, the parallel traces 422 in each X sensor 42 are electrically connected by conductive wires 424 made from the same conductor layer of the X sensors 42 and Y sensors and located in the gap between the parallel traces 422 as shown in FIG. 5, or by conductive wires provided elsewhere, e.g., the interconnections or peripheral traces of a printed circuit board.

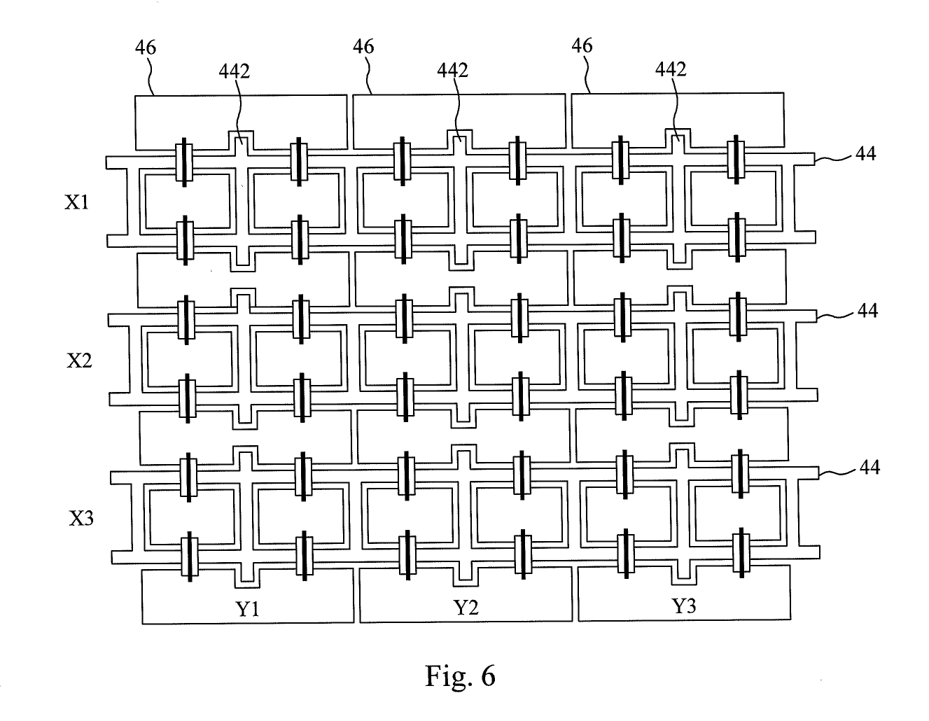

FIG. 6 is a schematic view of an embodiment modified from the embodiment shown in FIG. 5, in which each X sensor 44 is additionally provided with projections 442 extending in the Y direction so that each X sensor 44 has ragged edges and thus, the borders between each X sensor 44 and the Y sensors 46 are lengthened to increase the mutual capacitance therebetween and hence the sensing sensibility. In an embodiment, the borders between each X sensor 44 and the Y sensors 46 can be lengthened simply by changing the borders from smooth straight lines to rugged ones. In another embodiment, the borders between each X sensor and the Y sensors in the same conductor layer are serrated or wavy to be increased in length.

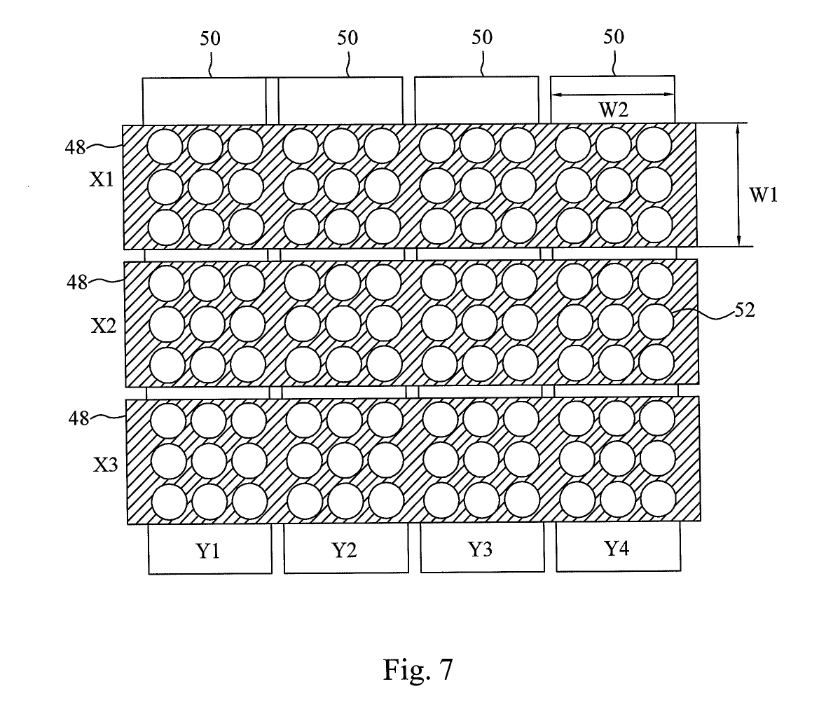

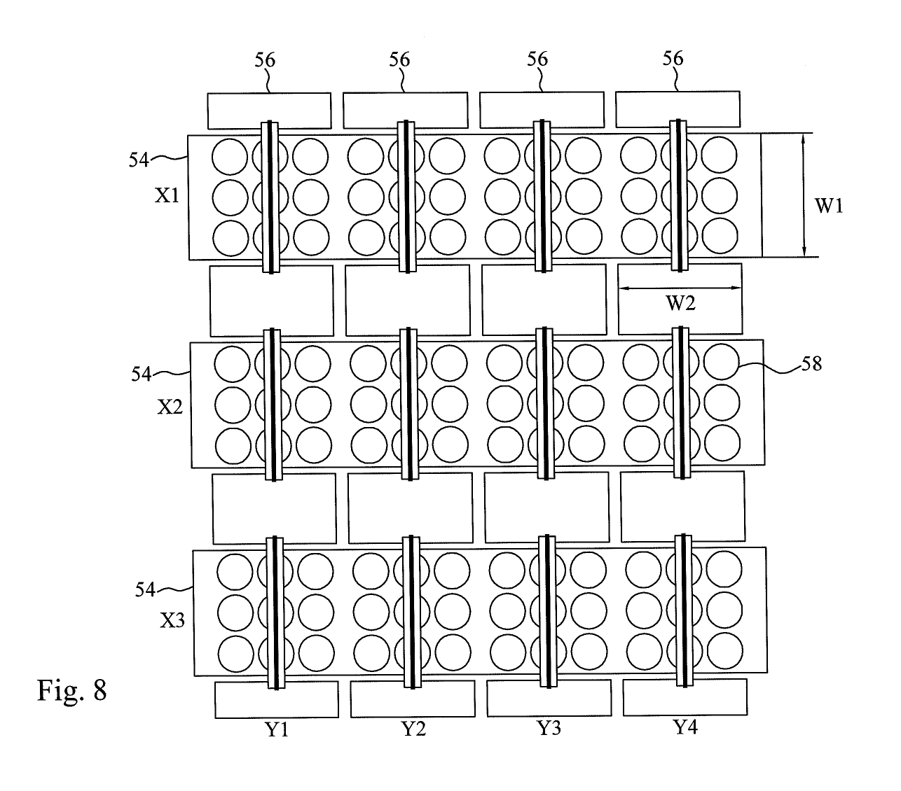

In addition to the width reduction approach already shown in the above embodiments, the sensing area of each X sensor can be reduced by providing holes distributed over the X sensor. FIG. 7 is a schematic view of an embodiment constructed by two conductor layers for X sensors 48 and Y sensors 50 respectively, as that shown in FIG. 2, while the width W1 of each X sensor 48 is the same as the width W2 of each Y sensor 50, but each X sensor 48 includes a plurality of holes 52 to significantly reduce the sensing area of each X sensor 48 to be much smaller than that of each Y sensor 50. FIG. 8 is a schematic view of an embodiment constructed by merely one conductor layer for X sensors 54 and Y sensors 56, as that shown in FIG. 4, in which the width W1 of each X sensor 54 is the same as the width W2 of each Y sensor 56, and each X sensor 54 includes a plurality of holes 58 to significantly reduce the sensing area thereof to be much smaller than that of each Y sensor 56. Using the hole-studded X sensors would not increase the spacing between the X sensors and thereby may remain the accuracy of identified position.

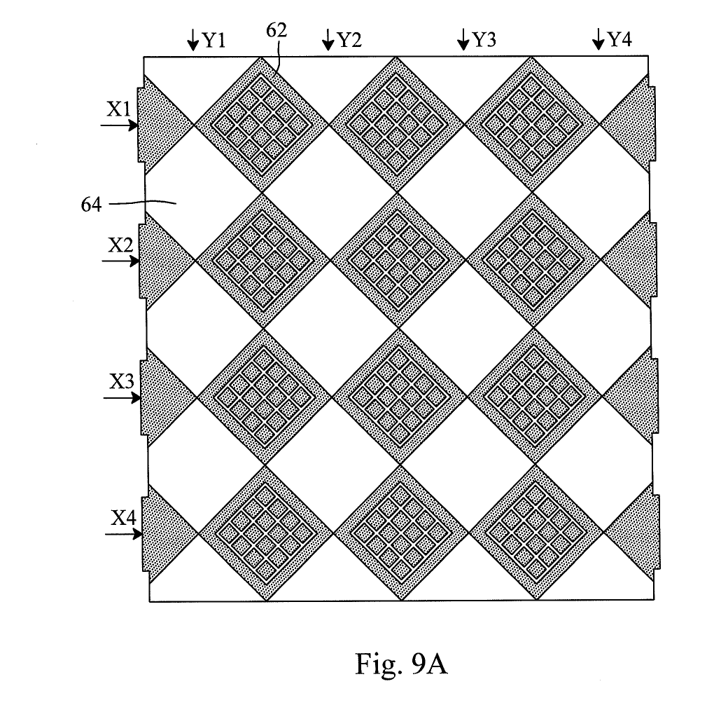

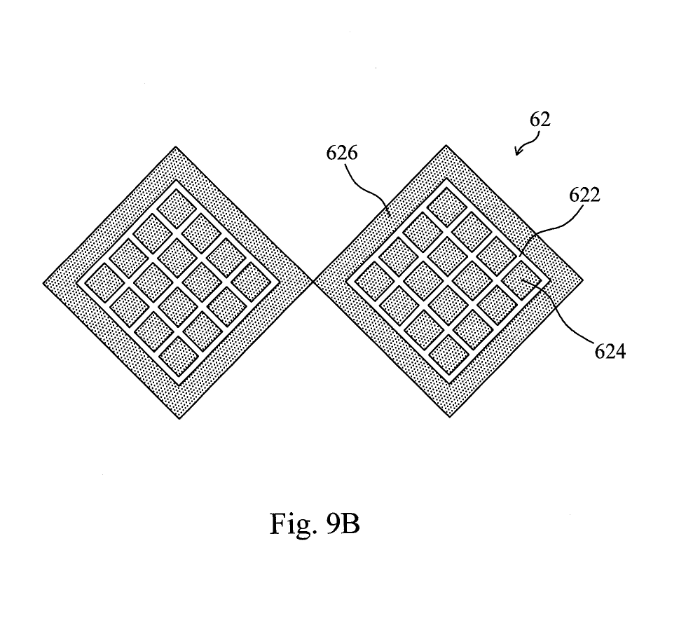

FIG. 9A is a schematic view of a further embodiment according to the present invention, in which each X sensor is constructed by a plurality of diamond-shaped sensing units 62 interconnected in series, and each Y sensor is constructed by a plurality of diamond-shaped sensing units 64 interconnected in series. All the diamond-shaped sensing units 62 and 64 have substantially a same dimension. It is appreciated that, however, the sensing unit 62 has a different effective sensing area from the sensing unit 64. Referring to FIG. 9B for clearer illustration, each sensing unit 62 in the X sensor has a hole 622 therein, whereas each sensing unit 64 in the Y sensor does not. Provided in each hole 622 is at least one dummy sensing piece 624 which is floating but not electrically connected to any surrounding conductors. In other words, each sensing unit 62 is hollowed out such that its effective sensing area consists only of the peripheral portion 626. Hence, the overall effective sensing area of each X sensor is much smaller than the effective sensing area of each Y sensor. For touch pads or touch screens using a transparent material, the provision of the dummy sensing pieces 624 in the holes 622 creates a more pleasing look. In the embodiment of FIG. 9A, sensors arranged in two perpendicular directions have substantially the same physical appearance but are provided with different effective sensing areas by the formation of holes in the X sensors.

The dummy sensing pieces shown in FIGS. 9A and 9B can be also applied to the other embodiments to provide a more pleasing look.

The embodiment of FIG. 9A is applicable to single conductor layer or two conductor layer touch control devices. In a single conductor layer touch control device, the X sensors and the Y sensors are on a same plane, and the conductive wires connecting the adjacent sections of each sensor in a certain direction are isolated from the sensors in the other direction by an insulator material. In a two conductor layer touch control device, the X sensors and the Y sensors are provided in two overlapping conductor layers respectively, and the two conductor layers are isolated from each other by an insulator material.

As would be understood by a person skilled in the art, the foregoing embodiments can be used in single conductor layer or multiple conductor layer touch control devices. In a single conductor layer touch control device, the X sensors and the Y sensors are isolated from each other by an insulator material where they intersect; therefore, the X sensors and the Y sensors are not electrically connected. In a multiple conductor layer touch control device, the X sensors and the Y sensors are located in two overlapping conductor layers and are isolated from each other by an insulator material.

The capacitance sensors according to the present invention can identify the touch position by sensing the mutual capacitance variation between the sensors in tow directions, no matter for single touch applications or multi-touch applications. Moreover, the capacitance sensors according to the present invention may use different materials to suit practical needs. For example, in touch screen applications, the capacitance sensors according to the present invention can be made of a transparent material such as indium tin oxide (ITO).

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A capacitance sensor structure, comprising:
a first sensor in a first direction, having a first sensing area;
a second sensor in a second direction, splitting into a plurality of parallel traces electrically connected together, having a second sensing area smaller than the first sensing area, and detected therefrom to sense a variation in a mutual capacitance between the first sensor and the second sensor; and
an insulator layer between the first sensor and the second sensor.

2. The capacitance sensor structure of claim 1, wherein an excitation signal is applied to the first sensor, and a response signal is detected from the second sensor for sensing the variation in a mutual capacitance between the first sensor and the second sensor.

3. The capacitance sensor structure of claim 2, further comprising a sensing circuit connected to the first sensor and the second sensor to apply the excitation signal and detect the response signal.

4. A capacitance sensor structure, comprising:
a first sensor in a first direction, having a first sensing area;
a second sensor in a second direction, having at least a hole and a second sensing area smaller than the first sensing area, and detected therefrom to sense a variation in a mutual capacitance between the first sensor and the second sensor; and
an insulator layer between the first sensor and the second sensor.

5. The capacitance sensor structure of claim 4, wherein an excitation signal is applied to the first sensor, and a response signal is detected from the second sensor for sensing the variation in a mutual capacitance between the first sensor and the second sensor.

6. The capacitance sensor structure of claim 5, further comprising a sensing circuit connected to the first sensor and the second sensor to apply the excitation signal and detect the response signal.

7. The capacitance sensor structure of claim 4, wherein each of the first and second sensor has a plurality of sensing units interconnected in series, and the at least a hole has at least a dummy piece therein.

8. A capacitance sensor structure, comprising:
a first sensor in a first direction, made from a conductor layer, and having a first sensing area; and
a second sensor in a second direction, made from the conductor layer, having a second sensing area smaller than the first sensing area, dividing the first sensor into a plurality of sections, and detected therefrom to sense a variation in a mutual capacitance between the first sensor and the second sensor; and
a bridge line spanning the second sensor to electrically connect two of the plurality of sections of the first sensor.

9. The capacitance sensor structure of claim 8, wherein an excitation signal is applied to the first sensor, and a response signal is detected from the second sensor for sensing the variation in a mutual capacitance between the first sensor and the second sensor.

10. The capacitance sensor structure of claim 9, further comprising a sensing circuit connected to the first sensor and the second sensor to apply the excitation signal and detect the response signal.

11. The capacitance sensor structure of claim 8, wherein the second sensor is split into a plurality of parallel trances electrically connected together.

12. The capacitance sensor structure of claim 8, wherein the first and second sensors have ragged borders therebetween.

13. The capacitance sensor structure of claim 8, wherein the second has a plurality of holes distributed thereover.

14. The capacitance sensor structure of claim 8, wherein the second sensor has at least a hole which has at least a dummy piece therein.
